(19) United States
(12) Patent Application Publication
(10) Pub. No.: US 2014/0229126 A1
(43) Pub. Date: Aug. 14, 2014

(54) FAULT DETECTION METHOD AND DEVICE

(71) Applicants: Xi Hu, Beijing (CN); Qing Gang Wang, Beijing (CN); Jian Hui Xing, Beijing (CN); Yue Zhuo, Beijing (CN)

(72) Inventors: Xi Hu, Beijing (CN); Qing Gang Wang, Beijing (CN); Jian Hui Xing, Beijing (CN); Yue Zhuo, Beijing (CN)

(21) Appl. No.: 14/233,359

(22) PCT Filed: Jul. 11, 2012
(86) PCT No.: PCT/EP2012/063540

§ 371 Date: Apr. 17, 2014

(30) Foreign Application Priority Data
Jul. 18, 2011 (DE) 201110200852.1

(51) Int. Cl. G01R 31/3185

(52) U.S. Cl. CPC G01R 31/318516
USPC 702/58

(57) ABSTRACT

A method and fault detection device for detecting faults in digital output channels includes a detection circuit for detecting a first level of a first detection point disposed before a switch and a load in the PLC system, detecting a second level of a second detection point disposed after the switch and load in the PLC system, and for outputting a corresponding first pulse signal according to a change in the first level and second levels, a judgment circuit for judging whether the pulse width of the received first pulse signal is within a permitted range and for outputting a second pulse signal when the judgment result is negative, a trigger circuit for triggering the display circuit according to the received second pulse signal, and a display circuit for displaying a detection result in response to a received signal.

### REFERENCE TO RELATED APPLICATIONS

This is a U.S. national stage of application No. PCT/EP2012/063540 filed 11 Jul. 2012. Priority is claimed on Chinese Application No. 201110200852.1 filed 18 Jul. 2011, the content of which is incorporated herein by reference in its entirety.

### BACKGROUND OF THE INVENTION

1. Field of the Invention

The present invention relates to the field of electricity and, more particularly, to a method and device for performing fault detection.

2. Description of the Related Art

In an industrial control system, external transient voltages, overcurrent or other factors will damage switches or drive circuits thereof, and a load will enter a short-circuit state. Thus, automatic testing of the connection state of digital output channels and the loads controlled thereby is absolutely necessary, whether they are fault protection digital output channels of a Programmable Logic Controller (PLC) with a fault protection function, fault protection digital output channels of a redundant PLC system used for an important process control system, or digital output channels of a standard PLC system.

In fault protection digital output channels, although there are already some automatic testing mechanisms, additional hardware and software systems that are unrelated to the control process must be added, and this will affect the operation of the load to a greater or lesser extent.

In standard PLC systems, an LED (light emitting diode) is added to indicate the output command (on/off) of each digital output channel. However, such a method is unable to reflect the actual operation situation of load connection or load disconnection by associated switch control, and is unable to reflect the load connection state. If a load control circuit has developed a fault, or the load has an open circuit or short circuit, such a method will be unable to detect this condition.

FIG. 8A shows a standard PLC digital output control system of the prior art; in FIG. 8A, only a partial illustrative drawing of this system is shown. This conventional system includes a computational module (a central controller or a distributed microcontroller in an I/O module), for generating a control signal which acts on a switch, controlling the power-up or power-down of a load by way of a switch drive circuit. The switch can be a MOSFET or a relay. The LED in the drawing is for indicating the control signal; if the channel is open, then the LED emits light, otherwise it does not.

FIG. 8B shows a fault protection digital output circuit of a fault protection PLC or a redundant PLC system of the prior art. Two switches are connected in series to provide a suitable control signal to the load; if one of these switches develops a fault, then the load cannot be powered up. This increases the reliability of the circuit, and is merely a fault redundancy technique, rather than a fault protection technique.

At present, only safety PLC systems or redundant PLC systems support on-line testing of load control circuits and the associated load connection situation. The patent documents EP 2 048 555 A1, U.S. Pat. No. 4,752,886 A, U.S. Pat. No. 4,868,826 A and US 2009/0219049 A1 provide relevant methods for on-line nondisruptive testing of switch operability and load connection status in important application scenarios. Here, fault identification is achieved by adding complex detection circuitry and specialized software modules. However, these “non-disruptive” testing methods are not truly nondisruptive, because as they still require temporary disconnection of the load during testing, and so cannot suit all types of load connection situations.

Hence, a device and method capable of testing the operability of digital output circuitry and load connection status online and displaying the same in real time are required for PLC systems.

### SUMMARY OF THE INVENTION

It is therefore an object of the present invention to provide a fault detection device to facilitate the detection of faults in PLC digital output channels in a non-disruptive manner, where the implementation is achieved in a simple and cost effective manner.

It is also an object of the present invention to provide a fault detection method, so that faults can be detected in PLC digital output channels by a simple method, achieving non-disruptive detection without the need for additional software equipment.

These and other objects and advantages are achieved in accordance with the invention by providing a fault detection device for application to a programmable logic controller (PLC) system, where the device comprises a detection circuit, a judgment circuit, a trigger circuit and a display circuit, where the detection circuit is for detecting a first level of a first detection point disposed before a switch and a load in the PLC system, detecting a second level of a second detection point disposed after the switch and the load in the PLC system, and for outputting a corresponding first pulse signal according to a change in the first level and the second level. The judgment circuit is for judging whether the received first pulse signal is within a permitted range, and for outputting a second pulse signal when the judgment result is negative. The trigger circuit is for triggering the display circuit according to the received second pulse signal. In addition, the display circuit is for displaying a detection result in response to a received signal.

In embodiments of the present invention, the detection circuit detects the output voltage signal of the PLC system and the voltage signal after passing through the switch and load. If the level states of the two are the same, i.e., when an inconsistent state occurs in the circuit, then the detection circuit outputs a pulse signal. If this pulse signal is not in the permitted range of the judgment circuit, then the judgment circuit outputs a pulse signal, so that the trigger circuit, on the basis of this signal, triggers the display circuit to display. Thus, faults are detected in the PLC system digital output channel by capturing pulse signals, with no need for the load to be disconnected, so that nondisruptive detection is achieved. The circuit structure is simple, with no need for large amounts of hardware resources or additional software equipment, such that costs are reduced and implementation is achieved relatively easily.

In preferred embodiments, the detection circuit further comprises a switch circuit, a load circuit, a photoelectric detection circuit and an output circuit, where the switch circuit has the input terminal thereof connected to the output terminal of a computational module in the PLC system, and the output terminal thereof connected to one end of the load circuit and a first input terminal of the photoelectric detection circuit, and is for executing a switching function. The load circuit has the other end thereof grounded, and is for providing a load for the circuitry. The photoelectric detection circuit has a second input terminal and a second output terminal thereof grounded, and a first output terminal thereof connected to a first input terminal of the output circuit, and is for isolating input signals from output signals. The output circuit has a second input terminal thereof connected to a first input terminal of the trigger circuit, and the output terminal thereof connected to the input terminal of the judgment circuit, and is for outputting a first pulse signal to the judgment circuit according to change in the first level and the second level.

In accordance with disclosed embodiments of the present invention, testing of the switch circuit and the load circuit are achieved by way of the photoelectric detection circuit and the output circuit. If the output voltage signal of the PLC and the output voltage signal after passing through the switch circuit and the load circuit have inconsistent states, then the output circuit will output a pulse signal to indicate to the judgment circuit to perform judgment on the output pulse signal. In this way, even if the change in the circuitry is slight, the detection circuit is still able to detect the change situation of the signal, making the detection result more accurate.

In preferred embodiments, the switch circuit comprises a switch driver circuit and a switch that is a field effect transistor, where the switch driver circuit has the input terminal thereof connected to the output terminal of the computational module and the output terminal thereof connected to the gate of the switch, the switch has the drain thereof connected to a first external power supply terminal and the source thereof connected to one end of the load circuit and a first input terminal of the photoelectric detection circuit, and the photoelectric detection circuit comprises a first resistance, a second resistance and an optocoupler; one end of the first resistance is connected to the source of the switch, while the other end thereof is connected to the anode of a light emitting diode in the optocoupler. One end of the second resistance is connected to a second external power supply terminal, while the other end thereof is connected to a first output terminal of the optocoupler and a first input terminal of the output circuit. The cathode of the light emitting diode in the optocoupler and a second output terminal of the optocoupler are grounded. The output circuit comprises an XNOR gate, with a second input terminal thereof connected to the output terminal of the computational module and the first input terminal of the trigger circuit, and the output terminal thereof connected to the input terminal of the judgment circuit.

Preferably, the judgment circuit comprises a judgment unit and a base unit, where the judgment unit is for judging whether the pulse width of the received first pulse signal is within the permitted range, and for outputting the second pulse signal when the judgment result is negative, and where the base unit is for filtering and buffering.

The judgment circuit in disclosed embodiments of the present invention can judge whether the pulse width of the received pulse signal is within the permitted range in accordance with an intrinsic inconsistent state duration stored therein, and can determine whether to output a pulse signal according to the judgment result. Determining whether a fault has occurred in accordance with the intrinsic state of the device makes the judgment on the fault more accurate.

Preferably, the judgment unit comprises a judgment chip, and the base unit comprises a first capacitance, a third resistance, a fourth resistance, a fifth resistance and a first transistor, where the first transistor is a triode. The judgment chip has a compensation pulse output pin thereof connected to one end of the fourth resistor, a pulse output pin thereof left vacant, a first trigger input pin thereof connected to a direct reset input pin and the second external power supply terminal, and a second trigger input pin thereof connected to one end of the fifth resistor and the output terminal of the detection circuit. The first capacitance is connected in series between an external resistance/capacitance connecting pin and an external capacitance connecting pin of the judgment chip, and that end thereof which is connected to the external capacitance/resistance connecting pin is also connected to one end of the third resistance. The other end of the third resistance is connected to the second external power supply terminal. The other end of the fourth resistance is connected to the base of the triode. The other end of the fifth resistance is connected to the collector of the triode and the second input terminal of the trigger circuit, and the emitter of the triode is grounded.

Preferably, the trigger circuit comprises a conversion unit and a trigger unit where the conversion unit is for converting a received signal, and the trigger unit is for triggering the display circuit according to the received signal.

The disclosed embodiments of the present invention employ a trigger circuit to trigger a display circuit according to a received signal. When the trigger circuit receives a pulse signal that is output by the judgment circuit, the trigger circuit outputs a low level signal to trigger the display circuit to display. Moreover, when the trigger circuit again receives an externally inputted reset signal, the trigger circuit will output a high level signal, i.e., it can automatically recover once a certain time has elapsed after fault prompting, and will not remain in the fault prompting state indefinitely.

Preferably, the conversion unit comprises a first converter and a second converter, while the trigger unit comprises a flip-flop. The detection circuit further comprises an XNOR gate, where the first converter has the input terminal thereof connected to the output terminal of the computational module in the PLC system and the second input terminal of the XNOR gate, and the output terminal thereof connected to a first input terminal of the display circuit. The second converter has the input terminal thereof connected to the output terminal of the judgment circuit, and the output terminal thereof connected to a first input terminal of the flip-flop. In addition, the flip-flop has a second input terminal thereof connected to an external reset signal terminal, a first output terminal thereof left vacant, and a second output terminal thereof connected to a second input terminal of the display circuit.

A specific circuit structure of the trigger circuit is provided in the embodiments of the present invention, so that those skilled in the art may easily implement the technical solution of the present invention. The flip-flop can be an RS flip-flop, the device used being simple, easy to implement and inexpensive. It should be understood that the specific circuit structure in the specific embodiments of the present invention is intended to explain the present invention and not to limit it, and other structures which could be used to implement the technical solution of the present invention are also included in the scope of protection thereof.

Preferably, the display circuit comprises a dual light emitting diode (LED) display device and a sixth resistance. The dual LED display device comprises a first LED and a second LED, where the cathode of the first LED is connected to the output terminal of the first converter, the cathode of the second LED is connected to the second output terminal of the flip-flop, the first LED and the second LED have a common anode, and the sixth resistance is connected in series between the anode and the second external power supply terminal.

As the embodiments of the present invention employ a dual LED display device for displaying, they can give different display effects for different situations, so that the tester can more accurately determine which specific fault has occurred by direct viewing, without the need for a further testing process.

According to another aspect of the embodiments of the present invention, a fault detection method is provided, for application to a programmable logic controller (PLC) system, and comprises detecting a first level of a first detection point disposed before a switch and a load in the PLC system, detecting a second level of a second detection point disposed after the switch and load in the PLC system, and outputting a corresponding first pulse signal according to a change in the first level and the second level. The method further comprises judging whether the received first pulse signal is in a permitted range, outputting a second pulse signal when the judgment result is negative, triggering a display circuit according to the received second pulse signal, and displaying a detection result in response to a received signal.

According to the method provided by the embodiments of the present invention, the fault situation of digital output channels of a PLC system can be detected with great convenience, with the detection result being displayed via a display circuit, where a tester can easily obtain a relatively accurate test result by direct viewing, so that faults can be located more readily.

Preferably, the detection step comprises detecting the first level of the first detection point disposed before the switch and load in the PLC system, detecting the second level of the second detection point disposed after the switch and load in the PLC system, and outputting the first pulse signal when the first level and the second level are in the same state, where the pulse width of the first pulse signal is the time for which the levels continue to be in the same state.

In disclosed embodiments of the present invention, the pulse width of the first pulse signal is the time for which the levels continue to be in the same state, so as to detect whether a fault has occurred in the circuitry via the pulse width of the first pulse signal, i.e., to judge whether a fault has occurred in the circuitry according to the time for which the levels continue to be in the same state, so that the judgment result is more accurate.

Preferably, the judgment step comprises comparing the pulse width of the received first pulse signal with a preset intrinsic inconsistent state duration, and outputting the second pulse signal if the pulse width of the received first pulse signal is greater than the intrinsic inconsistent state duration.

In disclosed embodiments of the present invention, the received first pulse signal is compared with a preset intrinsic inconsistent state duration, and a second pulse signal is output if the pulse width of the received signal is greater than the intrinsic inconsistent state duration. A judgment is then made on whether the received pulse signal is in the permitted range via the intrinsic inconsistent state duration of the device, so as to make the judgment result more accurate.

Employing the solution of the embodiments of the present invention reduces costs compared with existing technology, and it is simpler and easier to implement. Apart from the normal load control process, the fault detection solution in accordance with disclosed embodiments of the present invention does not require additional operations of switching in or disconnecting a load to test switch operation performance. It truly achieves nondisruptive testing, making the testing process more accurate, and can therefore be applied to any digital output channels with all kinds of different loads. The use of a dual LED display device for displaying in accordance with embodiments of the present invention not only makes displaying more accurate, but also enables a tester to acquire a testing result in a more intuitive way.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

The above characteristic, technical features, advantages and embodiments of the present invention will be described further below in a clear and easily comprehensible way, by describing preferable embodiments and with reference to the accompanying drawings, in which:

FIG. 1 is a block diagram of the main structure of the fault detection device in accordance with embodiments of the present invention;

FIG. 2 is a detailed circuit diagram of the fault detection device in accordance with embodiments of the present invention;

FIG. 3 is a sequence diagram of a detection circuit when no fault is present in accordance with embodiments of the present invention;

FIG. 4A is a sequence diagram of a detection circuit when the output signal continues to change after a switch fault;

FIG. 4B is a sequence diagram of a detection circuit when the output signal shows no further change after a switch fault;

FIG. 5A is a sequence diagram of a detection circuit when the output signal continues to change after a fault;

FIG. 5B is a sequence diagram of a detection circuit when the output signal shows no further change after a fault;

FIG. 6A is a sequence diagram of V4, V5 and V6 when a fault occurs in accordance with embodiments of the present invention;

FIG. 6B is a sequence diagram of V4, V5 and V6 when no fault is present in accordance with embodiments of the present invention;

FIG. 7 is a flow chart of the fault detection method in accordance with embodiments of the present invention;

FIG. 8A is a schematic diagram of a standard PLC digital output control system in accordance with the prior art;

FIG. 8B is a schematic diagram of a fault protection digital output circuit of a fault protection PLC or a redundant PLC system in accordance with the prior art.

### DETAILED DESCRIPTION OF THE PREFERRED EMBODIMENTS

In order that the technical features, objects and effects of the present invention may be understood more clearly, particular embodiments of the present invention will now be described with reference to the accompanying drawings, in which identical labels indicate identical parts. To show the relationships between various components clearly, the proportional relationships among the various components in the accompanying drawings are merely illustrative, and do not represent the proportional relationships in the actual structure.

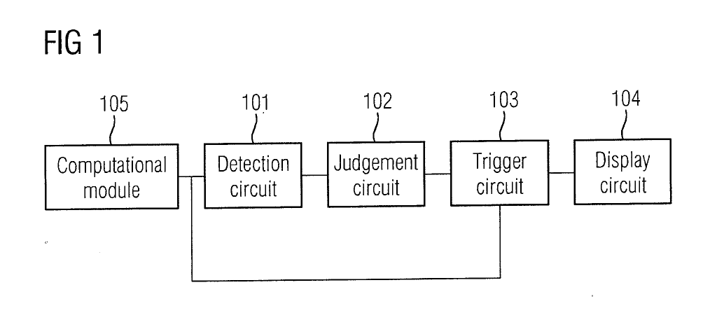

Referring to FIG. 1, the fault detection device of the embodiments of the present invention comprises a detection circuit 101, a judgment circuit 102, a trigger circuit 103 and a display circuit 104. The input terminal of the detection circuit 101 is connected to the output terminal of the device to be tested. For example, in embodiments of the present invention the device to be tested is the digital output channel of a PLC, so the input terminal of the detection circuit 101 can be connected to the output terminal of a computational module 105 of the PLC. The output terminal of the detection circuit 101 is connected to the input terminal of the judgment circuit 102, the output terminal of the judgment circuit 102 is connected to the input terminal of the trigger circuit 103, and the output terminal of the trigger circuit 103 is connected to the first input terminal of the display circuit 104.

The detection circuit 101 is for detecting a first level of a first detection point disposed before a switch and a load in the PLC system, detecting a second level of a second detection point disposed after the switch and load in the PLC system, and for outputting a corresponding first pulse signal according to a change in the first level and the second level. The detection circuit 101 performs testing of the switch and load. When a fault occurs in the switch, a switch driver circuit or the load, etc., or when such phenomena as delay cause inconsistent circuit output states, i.e., when the first output voltage signal of the computational module 105 in the PLC system (i.e. the first level) and the second output voltage signal after passing through the switch and load (i.e. the second level) are in the same level state, the detection circuit 101 outputs a step signal to the judgment circuit 102, which step signal can, for example, be a first pulse signal. The pulse width of the output first pulse signal depends upon the duration of the inconsistent state, i.e., it is equal to the duration of the inconsistent state.

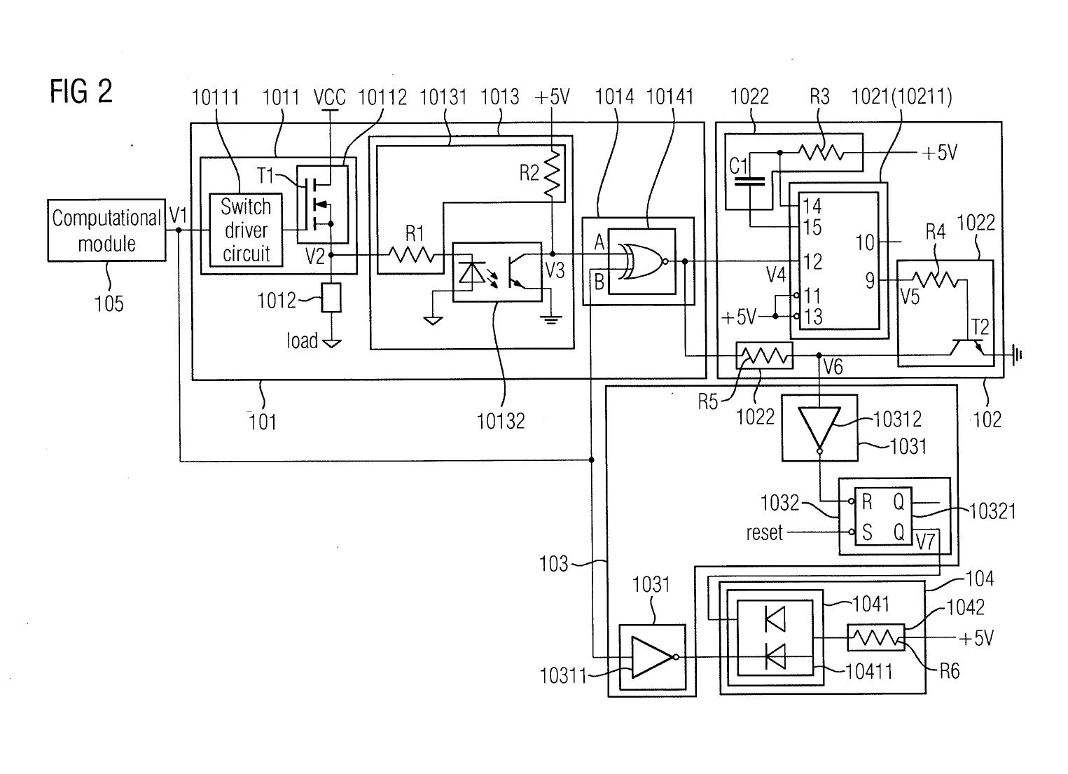

Shown in FIG. 2 is a detailed circuit diagram of the fault detection device in accordance with embodiments of the present invention. In FIG. 2, the detection circuit 101 comprises a switch circuit 1011, a load circuit 1012, a photoelectric detection circuit 1013 and an output circuit 1014. The input terminal of the switch circuit 1011 is connected to the output terminal of the computational module 105, while this output terminal of the computational module 105 is also connected to a second input terminal of the output circuit 1014 and a first input terminal of the trigger circuit 103. The output terminal of the switch circuit 1011 is connected to one end of the load circuit 1012 and a first input terminal of the photo electric detection circuit 1013. The other end of the load circuit 1012 is connected to ground (which can be analog ground). The photoelectric detection circuit 1013 has a second input terminal thereof connected to ground (which can be analog ground), a first output terminal thereof connected to a first input terminal of the output circuit 1014, and a second output terminal thereof connected to ground (which can be digital ground). The output circuit 1014 has the second input terminal thereof connected to the first input terminal of the trigger circuit 103, and the output terminal thereof connected to the input terminal of the judgment circuit 102.

The switch circuit 1011 comprises a switch driver circuit 10111 and a switch 10112. In disclosed embodiments of the present invention, the switch 10112 can be a field effect transistor (referred to hereinbelow as T1). The switch driver circuit 10111 has the input terminal thereof connected to the output terminal of the computational module 105, and the output terminal thereof connected to the gate of T1. Here, T1 has the drain thereof connected to a first external power supply terminal (DC Power Supply), i.e. the VCC terminal in FIG. 2, and the source thereof connected to one end of the load circuit 1012 and the first input terminal of the photoelectric detection circuit 1013. The switch circuit 1011 is mainly for executing a switching function. The load circuit 1012 is for providing a load for the circuitry. In FIG. 2, “load” is the load circuit 1012.

The photoelectric detection circuit 1013 comprises a resistance unit 10131 and an optocoupler 10132.The resistance unit 10131 comprises a first resistance (referred to hereinbelow as R1) and a second resistance (referred to hereinbelow as R2). R1 has one end thereof connected to the source of T1 (which end is referred to as the first input terminal of the photoelectric detection circuit 1013), and the other end thereof connected to the anode of a light emitting diode in the optocoupler 10132. One end of R2 is connected to a second external power supply terminal, which external power supply can be +5 V. The cathode of the light emitting diode in the optocoupler 10132 is connected to ground (which can be analog ground). A first output terminal of the optocoupler 10132 is connected to the other end of R2 and the first input terminal of the output circuit 1014, and the second output terminal of the optocoupler 10132 is connected to ground (which can be digital ground). The photoelectric detection circuit 1013 is mainly for isolating input signals from output signals.

The output circuit 1014 comprises an XNOR gate 10141. For instance, the XNOR gate 10141 can be implemented using an MC74HC266N chip. As shown in FIG. 2, the A terminal of the XNOR gate 10141 is the first input terminal of the output circuit 1014, while the B terminal thereof is the second in put terminal of the output circuit 1014. Here, the B terminal is connected to the output terminal of the computational module 105 and the first input terminal of the trigger circuit 103. The output circuit 1014 is mainly for outputting a first pulse signal to the judgment circuit 102 when an inconsistent state occurs in the circuitry, i.e., for outputting a first pulse signal to the judgment circuit 102 when the first level and the second level are in the same state.

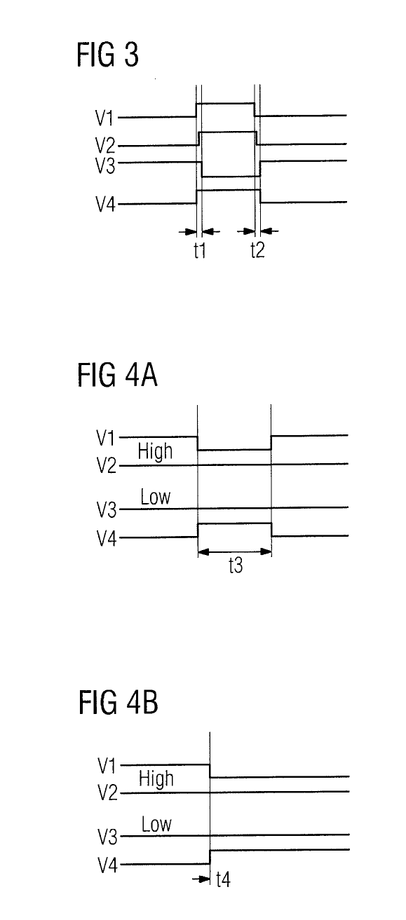

FIG. 3 is a sequence diagram of the detection circuit 101 when no fault is present in embodiments of the present invention. In the FIG. 3, V1 is the output voltage of the computational module 105, V2 is the output voltage of the source of T1, V3 is the output voltage of the first output terminal of the optocoupler 10132, i.e., the input voltage of the first input terminal of the output circuit 1014, and V4 is the output voltage of the output circuit 1014. The V1 point is referred to as the first detection point, and the level thereof is referred to as the first level. The V3 point is referred to as the second detection point, and the level thereof is referred to as the second level.

When the computational module 105 outputs a high level signal, i.e., V1 changes from low to high and operation under load begins, V2 will correspondingly change from low to high according to the change in V1, while V3 will correspondingly change from high to low. In an ideal situation, the changes in V1, V2 and V3 should be completed at the same instant, but in practice, it is possible that there may be switch powerup/power-down characteristics since the performance of devices cannot attain an ideal state. As a result, V2 and V3 may experience a delay before changing state. For example, in FIG. 3, V2 and V3 both have a delay, the delay time of V3 relative to V1 being t1, which is greater than the delay time of V2 relative to V1. If a relay was to be used as the switch in the detection circuit 101, a typical relay delay time might be several milliseconds, but a MOSFET (complementary metal oxide semiconductor field effect transistor) is used as the switch in embodiments of the present invention, and the delay time thereof does not in general exceed 1 millisecond. When V1 changes from high to low, V2 should correspondingly change from high to low and V3 should correspondingly change from low to high. At this time, V2 and V3 will experience a delay before changing state owing to the switch powerdown characteristics. For example, in FIG. 3, V2 and V3 both have a delay, the delay time of V3 relative to V1 being t2. It is precisely the delay arising from the switch powerup/power-down characteristics that results in a brief inconsistency of level states between V1 and V3 after a change in the output command, i.e., a situation in which the levels of V1 and V3 are in the same state will briefly occur. The output circuit 1014 will output a first pulse signal when it detects that V1 and V3 have the same level state. For example, in FIG. 3, the output circuit 1014 will output first pulse signals of pulse width t1 and t2, respectively. The output signal of the output circuit 1014 can be expressed as:

F=AB+AB Eq. (1)

where F is the output signal of the output circuit 1014. When the circuitry is in a consistent state, A and B have different level states and F is continuously 0, whereas when an inconsistent state occurs in the circuitry, A and B have the same level state and F is not 0, so that the output circuit 1014 will output a first pulse signal, which is V4. The maximum value of t1 and t2 can be estimated according to the device. This maximum value can be preset as the intrinsic in consistent state duration of the circuitry, and may be referred to as Tdiff.

As can be seen, the output circuit 1014 will output a first pulse signal V4 according to the change in each output signal V1 of the computational module 105, and real-time detection of faults in the load control circuit or the load can be performed by detecting the pulse width of the first pulse signals V4.

FIG. 4A and FIG. 4B are sequence diagrams of the detection circuit 101 when the switch has developed a fault in embodiments of the present invention. FIG. 4A is a sequence diagram of the detection circuit 101 when the output signal continues to change after a switch fault, while FIG. 4B is a sequence diagram of the detection circuit 101 when the output signal shows no further change after a switch fault. In FIG. 4A, the output signal V1 changes from high to low. Due to the switch fault, V2 has not correspondingly changed, and V3 will not change, so the output circuit 1014 will output a first pulse signal until V1 changes from low to high. The output circuit 1014 stops outputting the first pulse signal, and the pulse width of this first pulse signal is t3. In FIG. 4B, V1 has not changed after changing from high to low, and the pulse width of the first pulse signal is t4, starting from the moment when V1 changed from high to low and ending when V1 changes again from low to high.

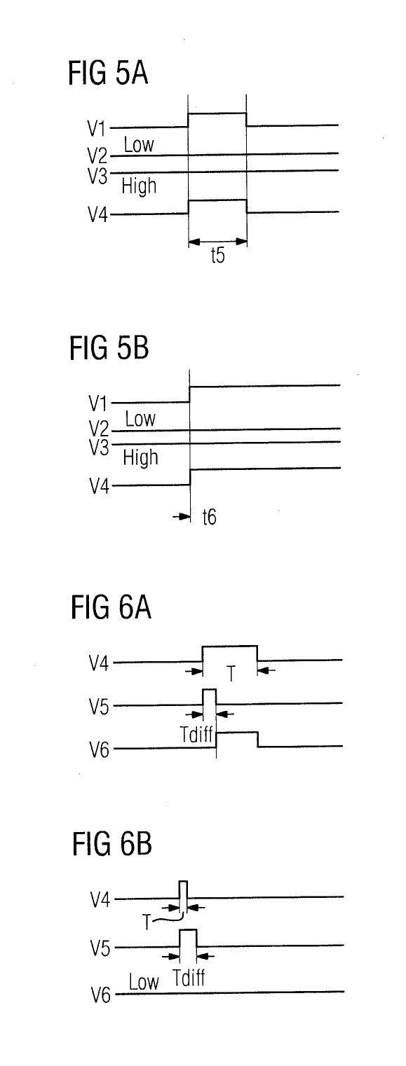

FIG. 5A and FIG. 5B are sequence diagrams of the detection circuit 101 when the load has no access to power or is shortcircuited as a result of a switch fault in embodiments of the present invention. FIG. 5A is a sequence diagram of the detection circuit 101 when the output signal continues to change after a fault, while FIG. 5B is a sequence diagram of the detection circuit 101 when the output signal shows no further change after a fault. In FIG. 5A, V1 changes from low to high. The load has no access to power or is short circuited perhaps as a result of a switch fault, thus V2 does not change correspondingly, and so V3 will not change either. The output circuit 1014 outputs a first pulse signal until V1 changes from high to low. The output circuit 1014 stops outputting the first pulse signal, and the pulse width of this pulse signal is t5. In FIG. 5B, V1 has not changed after changing from low to high, and the pulse width of the first pulse signal is t6, starting from the moment when V1 changed from low to high and ending when V1 changes again from high to low. Clearly, the pulse widths of t3, t4, t5 and t6 are all greater than Tdiff.

The judgment circuit 102 is for judging whether the pulse width of the received first pulse signal is in the permitted range, and for outputting a second pulse signal when the judgment result is negative. The judgment circuit 102 receives the first pulse signal output by the detection circuit 101. When an inconsistent state occurs in the circuitry, the XNOR gate in the detection circuit 101 outputs a first pulse signal to the judgment circuit 102, and the judgment circuit 102 judges whether the pulse width of the received first pulse signal is in the permitted range. If the pulse width exceeds the permitted range, the judgment circuit 102 outputs a signal. For example, the judgment circuit 102 can output a second pulse signal.

In FIG. 2, the judgment circuit 102 comprises a judgment unit 1021 and a base unit 1022. Specifically, the judgment unit 1021 can be a judgment chip 10211 for judging whether the received signal is within the permitted range. For example, the judgment chip can be a dual retriggerable-resettable monostable multivibrator, and the model number thereof can be 74HC4538. The base unit 1022 comprises a first capacitance (hereinafter referred to simply as CI), a third resistance (hereinafter referred to simply as R3), a fourth resistance (hereinafter referred to simply as R4), a fifth resistance (hereinafter referred to simply as RS) and a first transistor (hereinafter referred to simply as T2). This T2 can be a triode, and an NPN triode is used as an example in embodiments of the present invention. The 9th pin of the judgment chip 10211 (complementary pulse output) is connected to one end of R4, and the voltage signal output by this terminal is VS. The 10th pin (pulse output) is left vacant, the 11th pin (trigger input) and the 13th pin (direct reset input) are connected to each other and also connected to a second external power supply terminal. The 12th pin (trigger input) is connected to one end of RS and to the output terminal of the detection circuit 101, i.e., the output terminal of the XNOR gate 10141 in the detection circuit 101. CI is connected between the 14th pin (external resistor/capacitor connection) and the 15th pin (external capacitor connection) of the judgment chip 10211, while that end thereof which is connected to the 14th pin is also connected to one end of R3, with CI principally serving a filtering function. The other end of R3 is connected to the second external power supply terminal. The other end of R4 is connected to the base of T2, while the other end of RS is connected to the collector of T2 and the second input terminal of the trigger circuit 103; this terminal is also referred to as the output terminal of the judgment circuit 102, and the voltage thereof is V6. V6 can serve as an alarm signal for the PLC control system. The emitter of T2 is connected to ground (which can be digital ground). R3, R4 and RS all serve a buffering function. In the embodiments of the present invention, the 11th pin of the judgment chip 10211 can be referred to as the first trigger input pin, while the 12th pin can be referred to as the second trigger input pin. Moreover, the sizes of R3 and CI can be configured using the following formula:

Tdiff0.7*R3*C1 Eq. (2)

The value of Tdiff can be pre-stored in the judgment chip 10211. When the judgment chip 10211 receives a first pulse signal, then assuming the pulse width of this first pulse signal is T, the judgment chip judges the size relationship between T and Tdiff. If T is not greater than Tdiff, then the judgment chip 10211 does not output a signal. If T is greater than Tdiff, on the other hand, then the judgment chip 10211 outputs a 1 signal through the 9th pin. For example, it can output a second pulse signal, which can be used to drive T2.

FIG. 6A shows a sequence diagram of V4, V5 and V6 when a fault occurs in embodiments of the present invention. Assuming that the pulse width of the V4 pulse, i.e., the pulse width of the first pulse signal is T, the judgment chip will output a pulse signal (V5 in FIG. 6A) of pulse width Tdiff after receiving the V4 pulse signal. T in FIG. 6A is greater than Tdiff. As a result, the pulse width of the V6 pulse can be T Tdiff.

FIG. 6B shows a sequence diagram of V4, V5 and V6 when no fault is present in embodiments of the present invention. As seen from FIG. 6B, T2 does not produce a second pulse signal because the pulse width T of the V4 pulse is not greater than Tdiff, so V6 does not change.

The trigger circuit 103 is for triggering the display circuit 104 according to the received second pulse signal. The trigger circuit 103 comprises a conversion unit 1031 and a trigger unit 1032. The conversion unit 1031 comprises a first converter 10311 and a second converter 10312, for converting received signals. The first converter 10311 and second converter 10312 can both be NOT gates. For example, they may be implemented using MC54HC04. The trigger unit 1032 can be a flip-flop 10321, for example, an RS flip-flop, and can be implemented using 74LS279, for triggering the display circuit 104 according to the received signal. The second converter 10312 has the input terminal thereof (also referred to as the second input terminal of the trigger circuit 103) connected to the output terminal of the judgment circuit 102, and the output terminal thereof connected to the R′ terminal of the RS flip-flop. The first converter 10311 has the input terminal thereof (also referred to as the first input terminal of the trigger circuit 103) connected to the output terminal of the computational module 105 and the second input terminal of the XNOR gate 10141 in the detection circuit 101, and the output terminal thereof connected to the first input terminal of the display circuit 104. The R′ terminal of the RS flipflop can also be referred to as the first input terminal of the RS flip-flop, while the S′ terminal thereof can also be referred to as the second input terminal of the RS flip-flop. This second input terminal of the RS flip-flop is connected to an external reset signal terminal, i.e., the reset terminal in FIG. 2. The Q terminal is the first output terminal of the RS flip-flop. The Q′ terminal is the second output terminal of the RS flip-flop and is connected to the second input terminal of the display circuit 104, and has a voltage of V7.

The characteristic equation of the RS flip-flop can be expressed as:

Qⁿ⁺¹=S+ R̅Qⁿ Eq. (3)

When the trigger circuit 103 receives the second pulse signal output by the judgment circuit 102, the second converter 10312 inverts the received second pulse signal and sends it to the R′ terminal of the RS flip-flop. R′ is then 0, and the output signal of the Q′ terminal will change from a high level signal to a low level signal. The output signal of the Q′ terminal will only change again to a high level signal when the external reset signal terminal inputs a reset signal to the RS flip-flop. Thus, the trigger circuit 103 can output trigger signals to the display circuit 104 according to different output signals, making the display circuit 104 display.

The display circuit 104 is for displaying a detection result in response to a received signal. In FIG. 2, the display circuit 104 comprises a transistor unit 1041 and a resistance unit 1042. The transistor unit 1041 can comprise a dual LED display device 10411, while the resistance unit 1042 can comprise a sixth resistance (hereinbelow referred to as R6). Traditional detection methods all use one LED, whereas the present invention uses a detection method with a dual LED display device 10411 to make the detection result more accurate. The dual LED display device 10411 can comprise two LEDs, which can be a red LED and a green LED. In embodiments of the present invention, the green LED can be referred to as the first LED, while the red LED can be referred to as the second LED. The dual LED display device 10411 has 3 pins in total, with the two LEDs having a common anode and R6 being connected in series between the anode of the dual LED display device 10411 and the second external power supply terminal. The cathode of the green LED is connected to the output terminal of the first converter 10311, which terminal is referred to as the first input terminal of the display circuit 104, while the cathode of the red LED is connected to the second output terminal of the RS flip-flop, which terminal is referred to as the second input terminal of the display circuit 104.

As long as the output signal of the computational module 105 is high, the green LED in the dual LED display device 10411 emits light. If there is no fault in the circuitry, the trigger circuit 103 will not output a trigger signal. If in this case the output signal of the computational module 105 is high, the green LED in the dual LED display device 10411 emits light while the red LED does not, i.e., the dual LED display device 10411 displays a green light. If in this case the output signal of the computational module 105 is low, neither the green LED nor the red LED in the dual LED display device 10411 emits light, i.e., the dual LED display device 10411 does not emit light. If a fault occurs in the circuitry, the trigger circuit 103 outputs a trigger signal V7. If in this case the output signal of the computational module 105 is high, both the green LED and the red LED in the dual LED display device 10411 emit light, so that the dual LED display device 10411 displays a yellow light. If in this case the output signal of the computational module 105 is low. However, the green LED in the dual LED display device 10411 does not emit light while the red LED does, i.e., the dual LED display device 10411 displays a red light. Table 1 below gives the relationships between output commands, the load connection condition/load control circuit condition and the LED display state.

TABLE 1

| | Load connection | Dual LED | Green LED | Red LED |
|---|---|---|---|---|
| Output | & load control | display | in the dual | in the dual |
| command | circuit | device | LED display | LED display |
| 0 | Normal | Not lit | Not lit | Not lit |
| 0 | Fault | Red | Not lit | Lit |
| 1 | Normal | Green | Lit | Not lit |
| 1 | Fault | Yellow | Lit | Lit |

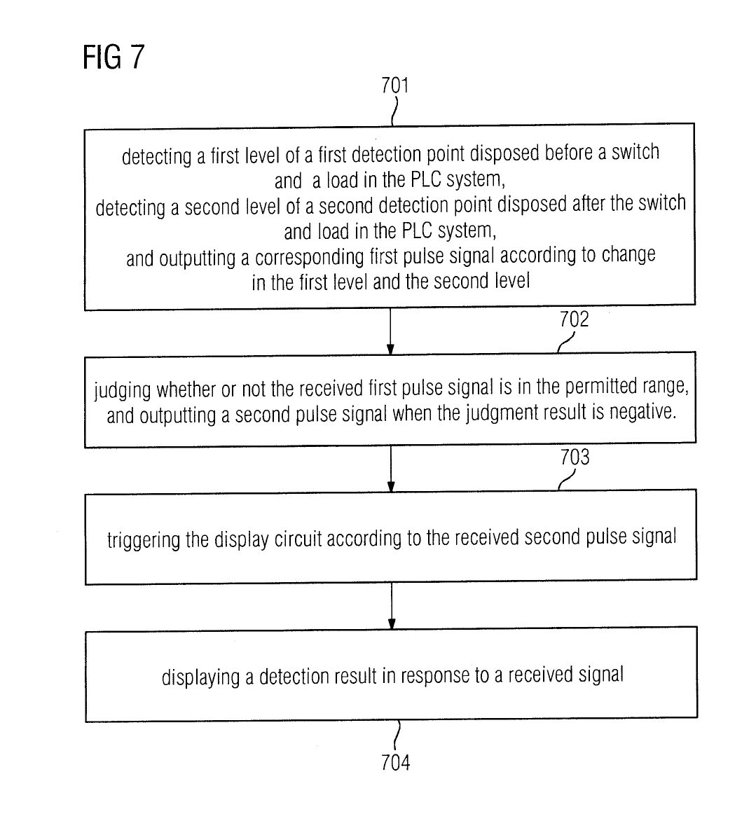

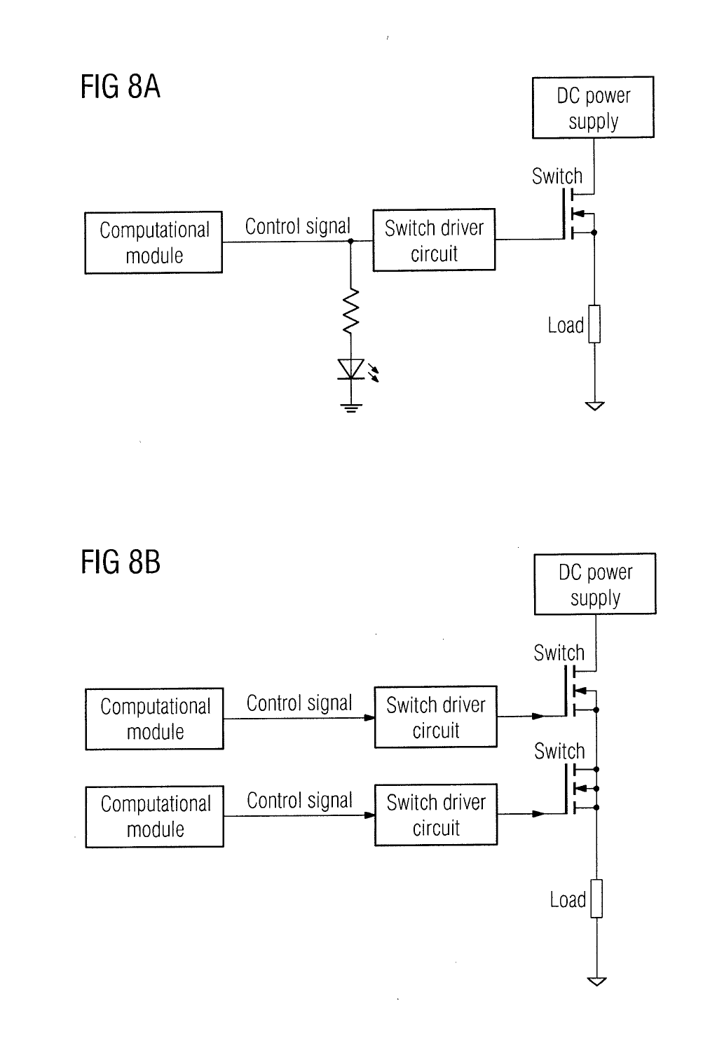

With reference to FIG. 7, which is a flow chart of the fault detection method in accordance with embodiments of the present invention, the method comprises Step 701: a detection step of detecting a first level of a first detection point disposed before a switch and a load in the PLC system, detecting a second level of a second detection point disposed after the switch and load in the PLC system, and outputting a corresponding first pulse signal according to change in the first level and the second level. Step 702: a judgment step, for judging whether the received first pulse signal is in a permitted range, and outputting a second pulse signal when the judgment result is negative. Step 703: a triggering step, for triggering a display circuit according to the received second pulse signal, Step 704: a displaying step, for displaying a detection result in response to a received signal.

The fault detection device in embodiments of the present invention is applied to a programmable logic controller (PLC) system, and comprises a detection circuit 101, a judgment circuit 102, a trigger circuit 103 and a display circuit 104. The detection circuit 101 has the output terminal thereof connected to the input terminal of the judgment circuit 102, and is for detecting a first level of a first detection point disposed before a switch and a load in the PLC system, for detecting a second level of a second detection point disposed after the switch and load in the PLC system, and for outputting a corresponding first pulse signal according to a change in the first level and the second level. The judgment circuit 102 has the output terminal thereof connected to the input terminal of the trigger circuit 103, and is for judging whether the received first pulse signal is within the permitted range, and for outputting a second pulse signal when the judgment result is negative. The trigger circuit 103 has the output terminal thereof connected to the input terminal of the display circuit 104, and is for triggering the display circuit 104 according to the received second pulse signal; the display circuit 104 is for displaying a detection result in response to a received signal.

Employing the solution of the disclosed embodiments of the present invention reduces costs compared with existing technology, and it is simpler and easier to implement. Apart from the normal load control process, the fault detection solution in accordance with the disclosed embodiments of the present invention does not require additional operations of switching in or disconnecting a load to test switch operation performance; it truly achieves nondisruptive testing, making the testing process more accurate, and can therefore be applied to any digital output channels with all kinds of different loads. The use of a dual LED display device for displaying within the embodiments of the present invention not only makes displaying more accurate, but also enables a tester to acquire a testing result in a more intuitive way.

The present invention has been set forth and described in detail above by way of accompanying drawings and preferable embodiments, but is not restricted to these disclosed embodiments; other solutions deduced therefrom by those skilled in the art also fall within the scope of protection of the present invention.

Thus, while there have shown, described and pointed out fundamental novel features of the invention as applied to a preferred embodiment thereof, it will be understood that various omissions and substitutions and changes in the form and details of the devices illustrated, and in their operation, may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

1.-11. (canceled)

12. A fault detection circuit for a programmable logic controller (PLC) system, comprising:
a detection circuit for detecting a first level of a first detection point disposed before a switch and a load in the PLC system, detecting a second level of a second detection point disposed after the switch and the load in the PLC system, and outputting a corresponding first pulse signal according to a change in the first level and second levels;
a judgment circuit for judging whether a pulse width of a received first pulse signal is within a permitted range, and outputting a second pulse signal when the judgment result is negative;
a trigger circuit; and
a display circuit for displaying a detection result in response to a received signal;
wherein the trigger circuit triggers the display circuit according to a received second pulse signal.

13. The device as claimed in claim 12, wherein the detection circuit comprises:
a switch circuit;
a load circuit;
a photoelectric detection circuit; and
an output circuit;
wherein the switch circuit includes an input terminal thereof connected to an output terminal of a computational module in the PLC system, and the output terminal thereof connected to one end of the load circuit and a first input terminal of the photoelectric detection circuit, the switching circuit executing a switching function;
wherein the load circuit has another end thereof grounded and provides a load for the circuitry;
wherein the photoelectric detection circuit has a second input terminal and a second output terminal thereof grounded, and a first output terminal thereof connected to a first input terminal of the output circuit, photoelectric detection circuit isolating input signals from output signals; and
wherein the output circuit has a second input terminal thereof connected to a first input terminal of the trigger circuit, and an output terminal thereof connected to the input terminal of the judgment circuit, the output circuit outputting a first pulse signal to the judgment circuit according to change in the first level and second levels.

14. The device as claimed in claim 13, wherein the switch circuit comprises:
a switch driver circuit and a switch, the switch driver circuit comprising a field effect transistor;
wherein the switch driver circuit has an input terminal thereof connected to an output terminal of the computational module and an output terminal thereof connected to a gate of the switch driver circuit;
wherein the switch driver circuit has a drain thereof connected to a first external power supply terminal, and a source thereof connected to one end of the load circuit and a first input terminal of the photoelectric detection circuit;
wherein the photoelectric detection circuit comprises a first resistance, a second resistance and an optocoupler, one end of the first resistance being connected to the source of the switch, and another end thereof being connected to an anode of a light emitting diode in the optocoupler, one end of the second resistance being connected to a second external power supply terminal, and another end thereof being connected to a first output terminal of the optocoupler and a first input terminal of the output circuit;
wherein a cathode of the light emitting diode in the optocoupler and a second output terminal of the opto coupler are grounded; and
wherein the output circuit comprises an XNOR gate having a second input terminal connected to the output terminal of the computational module and a first input terminal of a trigger circuit, an output terminal of the XNOR gate being connected to an input terminal of the judgment circuit.

15. The device as claimed in claim 12, wherein the judgment circuit comprises:
a judgment unit for judging whether the pulse width of the received first pulse signal is within the permitted range, and outputting the second pulse signal when the judgment result is negative; the base unit; and
a base unit for filtering and buffering.

16. The device as claimed in claim 15, wherein the judgment unit comprises:
a judgment chip, and the base unit comprises a first capacitance, a third resistance, a fourth resistance, a fifth resistance, and a first transistor comprising a triode;
wherein the judgment chip has a compensation pulse output pin thereof connected to one end of the fourth resistor, a pulse output pin thereof being vacant, a first trigger input pin thereof connected to a direct reset input pin and a second external power supply terminal, and a second trigger input pin thereof connected to one end of the fifth resistor and the output terminal of the detection circuit, the first capacitance being connected in series between an external resistance/capacitance connecting pin and an external capacitance connecting pin of the judgment chip; and
wherein that end thereof which is connected to the external capacitance/resistance connecting pin is also connected to one end of the third resistance, another end of the third resistance being connected to the second external power supply terminal, another end of the fourth resistance being connected to the base of the triode, another end of the fifth resistance being connected to a collector of the triode and the second input terminal of the trigger circuit, and an emitter of the triode being grounded.

17. The device as claimed in claim 12, wherein the trigger circuit comprises:
a conversion unit for converting a received signal; and
a trigger unit for triggering the display circuit according to the received signal.

18. The device as claimed in claim 17, wherein the conversion unit comprises a first converter and a second converter;
wherein the trigger unit comprises a flip-flop;
wherein the detection circuit further comprises an XNOR gate;
wherein the first converter has an input terminal thereof connected to the output terminal of the computational module in the PLC system and the second input terminal of the XNOR gate, and an output terminal thereof connected to a first input terminal of-the display circuit;
wherein the second converter has an input terminal thereof connected to the output terminal of the judgment circuit, and an output terminal thereof connected to a first input terminal of a flip-flop having a second input terminal thereof connected to an external reset signal terminal, a first output terminal being vacant, and a second output terminal thereof connected to a second input terminal of the display circuit.

19. The device as claimed in claim 18, wherein the display circuit comprises a dual light emitting diode (LED) display device and a sixth resistance;
wherein the dual LED display device comprises a first LED and a second LED, a cathode of the first LED being connected to an output terminal of the first converter, a cathode of the second LED being connected to the second output terminal of the flip-flop, the first LED and the second LED having a common anode, and the sixth resistance being connected in series between an anode and the second external power supply terminal.

20. A fault detection method for a programmable logic controller (PLC) system, the method comprising:
detecting a first level of a first detection point disposed before a switch and a load in the PLC system, detecting a second level of a second detection point disposed after the switch and the load in the PLC system, and outputting a corresponding first pulse signal according to a change in the first and second levels;
judging whether a received first pulse signal is in a permitted range, and outputting a second pulse signal when the judgment result is negative;
triggering a display circuit according to the received second pulse signal; and
displaying a detection result in response to a received signal.

21. The method as claimed in claim 20, wherein the detection step comprises:
detecting the first level of the first detection point disposed before the switch and the load in the PLC system;
detecting the second level of the second detection point disposed after the switch and the load in the PLC system; and
outputting the first pulse signal when the first and second levels are in the same state, a pulse width (T) of the first pulse signal being a time during which the first and second levels continue to be in the same state.

22. The method as claimed in claim 9, wherein the judgment step comprises:
comparing the pulse width (T) of the received first pulse signal with a preset intrinsic inconsistent state duration (Tdiff), and outputting the second pulse signal if the pulse width (T) of the received first pulse signal is greater than the intrinsic inconsistent state duration (Tdiff).
